(19) United States
(12) Patent Application Publication
(10) Pub. No.: US 2003/0015292 A1
(43) Pub. Date: Jan. 23, 2003

(54) Apparatus for fabricating a semiconductor device

(76) Inventors: Chul Ju Hwang, Kyonggi-do (KR); Kyung Sik Shim, Kyonggi-do (KR)

Correspondence Address: Marger Johnson & McCollom, 1030 SW Morrison Street, Portland, OR, 97205, US

(21) Appl. No.: 09/913,665

(22) PCT Filed: Dec. 15, 2000
(86) PCT No.: PCT/KR00/01467

(51) Int. Cl. C23F 1/00; C23C 16/00

(52) U.S. Cl. 156/345.47; 118/723 E

(57) ABSTRACT

An apparatus for an apparatus for fabricating a semiconductor device comprising: an electrically grounded reactor for providing a reaction space sealed from the outer atmosphere; a susceptor for settling a wafer and arranged within the reactor to prevent electric connection to the reactor; a plasma electrode provided around the upper part of the reactor; an RF power supply electrically connected to the susceptor and the plasma electrode to provide RF power to the same; and an RF relay for applying the RF power supplied from the RF power supply to at least one of the susceptor and the plasma electrode. According to the apparatus, the optimal plasma atmosphere can be easily generated for a certain process without any additional plasma electrode. Furthermore, cleaning around the susceptor can be efficiently carried out by using the susceptor as a plasma electrode.

### TECHNICAL FIELD

The present invention relates to an apparatus for fabricating a semiconductor device, and more particularly to an apparatus for fabricating a semiconductor device having a susceptor which is designed as a plasma electrode.

### BACKGROUND ART

In an apparatus for fabricating a semiconductor device in which a thin film is etched or deposited by using plasma, a plasma electrode is generally fixed at one place. Therefore, process margin is small, and in cleaning the inside of a reactor by using plasma after a thin film deposition process, at least a part of the inside is not cleaned sufficiently. Therefore, in order to improve process margin or clean the inside of a reactor sufficiently, the apparatus is required to comprise an additional plasma electrode, which undesirably increases cost.

FIG. 1 is a schematic view for illustrating an apparatus for fabricating a semiconductor device of the prior art.

Referring to FIG. 1, a reactor which defines a reaction space sealed from the outer atmosphere is provided with a chamber 10 and a quartz dome 20 which covers the upper part of the chamber 10. The chamber 10 is grounded, and a plasma electrode 30 is provided around the quartz dome 20 to cover the same. The plasma electrode 30 is supplied with RF(radio frequency) power from an RF power supply 70.

A substrate transport port 60 is provided in the side wall of the chamber 10. The substrate transport port 60 serves as a passage so that a wafer 50 may be loaded into the chamber 10 through the same. A susceptor 40 is arranged within the chamber 10 to support the loaded wafer which is settled thereon, and has a heater 40a for heating the wafer 50 in the inside thereof. Opening/closing of the substrate transport port 60 is controlled by a slot valve 60a. The susceptor 40 can be displaced up and down by a susceptor supporting means 45 which is made with an insulating material to prevent any electrical connection between the chamber 10 and the susceptor 40. With this construction, the susceptor 40 is electrically floated. A gas inlet for introducing gas into the reactor or a gas outlet for exhausting gas out of the reactor is not shown for the sake of brevity.

According to the apparatus for fabricating a semiconductor device of the prior art as described above, it is difficult to form the optimal plasma environments for carrying out a process efficiently since the plasma electrode 30 is fixed at the upper part of the reactor. Also, when trying to eliminate a thin film which is undesirably deposited on the inner surface of the reactor after a PECVD(plasma enhanced chemical vapor deposition) process, the deposited thin film is not easily eliminated since plasma fails to reach the space under the susceptor 40. The thin film deposited on the inner surface of the reactor like this is partly peeled off later, thereby building up undesired particles.

### DISCLOSURE OF THE INVENTION

Therefore, it is an object of the present invention to provide an apparatus for fabricating a semiconductor device, in which the optimal plasma environments for carrying out an efficient process can be formed, and the reactor of the apparatus can be cleaned sufficiently in every place of the inside thereof when cleaned by using plasma.

According to an embodiment of the present invention to obtain the foregoing objects, it is provided an apparatus for fabricating a semiconductor device comprising: an electrically grounded reactor for providing a reaction space sealed from the outer atmosphere; a susceptor for settling a wafer and arranged within the reactor to prevent electric connection to the reactor; a plasma electrode provided around the upper part of the reactor; an RF power supply electrically connected to the susceptor and the plasma electrode to provide RF power to the same; and an RF relay for applying the RF power supplied from the RF power supply to at least one of the susceptor and the plasma electrode.

It is preferred that the apparatus for fabricating a semiconductor device further comprises a ground relay for controlling an electrical connection of the plasma electrode and the reactor.

It is also preferred that the ground relay can disable electric connection between the plasma electrode and the reactor when the RF relay disables electric connection between the RF power supply and the susceptor while enabling electric connection between the RF power supply and the plasma electrode.

Also, it is preferred that the ground relay can enable electric connection between the plasma electrode and the reactor when the RF relay disables electric connection between the RF power supply and the plasma electrode while enabling electric connection between the RF power supply and the susceptor.

According to the preferred embodiment of the present invention as described above, RF power supplied from an RF power supply can be alternatively applied to a susceptor and a plasma electrode without difficulty by using the RF relay. Therefore, the optimal plasma atmosphere can be easily generated for a certain process without any additional plasma electrode. Also, when trying to eliminate a thin film which is undesirably deposited on the inner side of the chamber after a PECVD(plasma enhanced chemical vapor deposition) process which uses plasma generated by the plasma electrode, cleaning around the susceptor can be efficiently carried out by using the susceptor as a plasma electrode. Furthermore, an HDP(high density plasma) process can be also easily carried out since RF power can be simultaneously applied to susceptor and the plasma electrode.

### BRIEF DESCRIPTION OF THE DRAWINGS

The above object and advantages of the present invention will become more apparent by describing in detail a preferred embodiment thereof with reference to the attached drawings in which:

FIG. 1 is a schematic view for illustrating an apparatus for fabricating a semiconductor device of the prior art; and

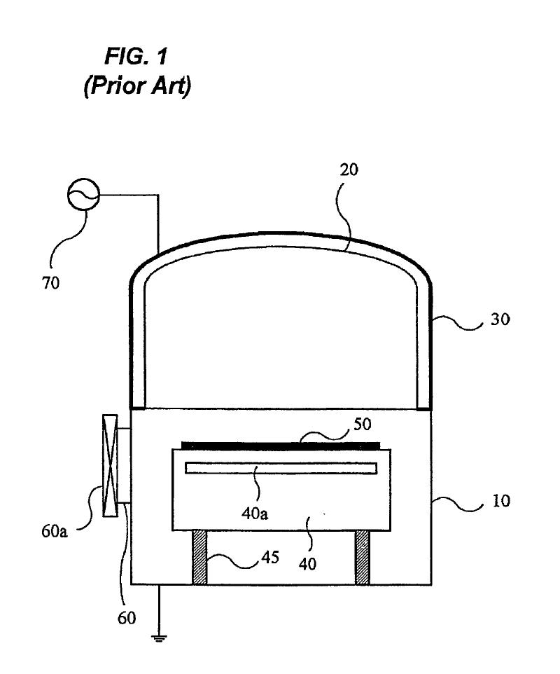

FIG. 2 is a schematic view for illustrating an apparatus for fabricating a semiconductor device of the present invention.

### BEST MODE FOR CARRYING OUT THE INVENTION

The preferred embodiment of the present invention will be described in detail with the reference to the accompanying drawings.

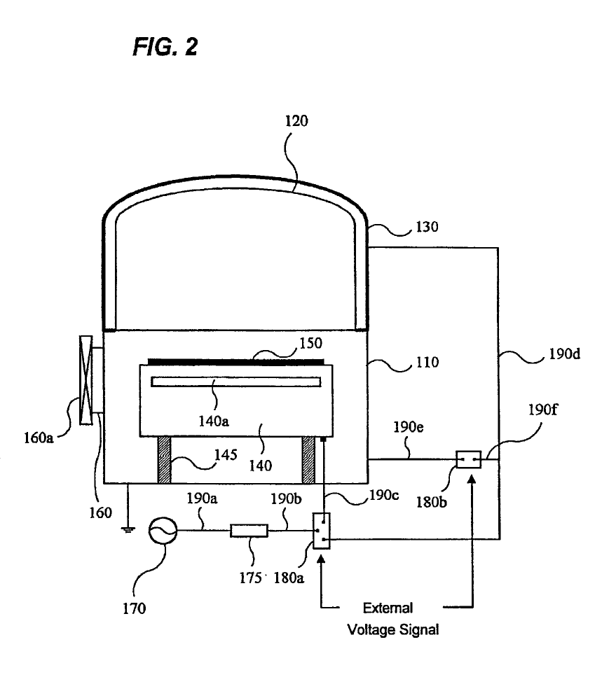

FIG. 2 is a schematic view for illustrating an apparatus for fabricating a semiconductor device of the present invention.

Referring to FIG. 2, a reactor which defines a reaction space sealed from the outer atmosphere is provided with a chamber 110 and a quartz dome 120 which covers the upper part of the reactor. The chamber 110 is grounded, and a plasma electrode 130 is provided around the quartz dome 120 to cover the same.

A substrate transport port 160 is provided in the side wall of the chamber 110. The substrate transport port 160 serves so that a wafer 50 may be loaded into the chamber 10 through the same. A susceptor 140 is arranged within the chamber 110 to support the loaded wafer 150 which is settled thereon and, has a heater 140a for heating the wafer 150 in the inside thereof. Opening/closing of the susceptor transport pipe 160 is controlled by a slot valve 160a The susceptor 140 can be displaced up and down by a susceptor supporting means 145 which is made with an insulating material to prevent any electrical connection between the chamber 110 and the susceptor 140. With this construction, the susceptor 140 is electrically floated. A gas inlet for introducing gas into the reactor or a gas outlet for exhausting gas out of the reactor is not shown for the sake of brevity.

An RF power supply 170 is connected to a matching box 175 via first power line 190a, and the matching box 175 is connected to an RF relay 180a via second power line 190b. The RF relay 180a is connected to the susceptor 140 via third power line 190c, and to the plasma electrode 130 via fourth power line 190d, respectively. The reactor 110 is connected to a ground relay 180b via fifth power line 190e, and the ground relay 180b is connected to the fourth power line 190d via sixth power line 190f.

The matching box 175 matches RF power supplied from the RF power supply 170 via the first power line 190a to have the minimum reflectance, and then supplies the matched RF power to the RF relay 180a via the second power line 190b.

Herein after it will be described about the operation of the RF relays 180a, 180b according to input of an external voltage signal of 24V, for example.

The RF relay 180a, when the external voltage signal of 24V is not inputted thereto, enables electric connection only between the second and fourth power lines 190b, 190d so that RF power can be applied only to the plasma electrode 130. At the same time, the external voltage signal of 24V is inputted to the ground relay 180b also, and then the ground relay 180b disables electric connection between the fifth and the sixth power lines 190e, 190f. Therefore, in this case, plasma is generated within the chamber 110 by the RF power applied to the plasma electrode 130 while the susceptor 140 is floated and the chamber 110 is grounded.

The RF relay 180a, when the external voltage signal is applied thereto, enables electric connection only between the second and the third power lines 190b, 190c so that RF power can be applied only to susceptor 140. At the same time, the external voltage signal is inputted to the ground relay 180b, and then the ground relay 180b enables electric connection between the fifth and the sixth power lines 190e, 190f. Therefore, in this case, plasma is generated within the chamber 110 by the RF power applied to the susceptor 140 while the plasma electrode 130 and the chamber 110 are grounded.

Even though it is not described above, in addition to enabling the RF power to be alternatively applied to the susceptor 140 and the plasma electrode 130, the RF relay 180a may also connect the second power line 190b to both of the third and the fourth power lines 190c, 190d so that the RF power can be applied to the susceptor 140 and the plasma electrode 130 simultaneously.

### Industrial Applicability

According to the preferred embodiment of the present invention as described above, RF power supplied from an RF power supply can be alternatively applied to a susceptor and a plasma electrode without difficulty by using the RF relay. Therefore, the optimal plasma atmosphere can be easily generated for a certain process without any additional plasma electrode. Also, when trying to eliminate a thin film which is undesirably deposited on the inner side of the chamber after a PECVD(plasma enhanced chemical vapor deposition) process which uses plasma generated by the plasma electrode, cleaning around the susceptor can be efficiently carried out by using the susceptor as a plasma electrode. Furthermore, an HDP(high density plasma) process can be also easily carried out since RF power can be simultaneously applied to susceptor and the plasma electrode.

Herein above the invention has been described in reference to the preferred embodiment, but various other modifications and variations will be apparent to those skilled in the art without departing from the scope and spirit of the present invention.

What is claimed is:

1. An apparatus for fabricating a semiconductor device comprising:
an electrically grounded reactor for providing a reaction space sealed from the outer atmosphere;
a susceptor for settling a wafer and arranged within said reactor to prevent electric connection to said reactor;
a plasma electrode provided around the upper part of said reactor;
an RF power supply electrically connected to said susceptor and said plasma electrode to provide RF power to the same; and
an RF relay for applying the RF power supplied from said RF power supply to at least one of said susceptor and said plasma electrode.

2. The apparatus for fabricating a semiconductor device according to claim 1, further comprising a ground relay for controlling an electrical connection of said plasma electrode and said reactor.

3. The apparatus for fabricating a semiconductor device according to claim 2, wherein said ground relay disables electric connection between said plasma electrode and the reactor when said RF relay disables electric connection between said RF power supply and said susceptor while enabling electric connection between said RF power supply and said plasma electrode.

4. The apparatus for fabricating a semiconductor device according to claim 2, wherein said ground relay enables electric connection between said plasma electrode and said reactor when said RF relay disables electric connection between said RF power supply and said plasma electrode while enabling electric connection between said RF power supply and said susceptor.

5. The apparatus for fabricating a semiconductor device according to claim 3, wherein said RF relay and said ground relay receive same external voltage signal at the same time.

6. The apparatus for fabricating a semiconductor device according to claim 4, wherein said RF relay and said ground relay receive same external voltage signal at the same time.
